(19) United States
(12) Patent Application Publication
(10) Pub. No.: US 2024/0420961 A1
(43) Pub. Date: Dec. 19, 2024

(54) METHOD OF MANUFACTURING SEMICONDUCTOR DEVICE

(71) Applicant: SAMSUNG ELECTRONICS CO., LTD., Suwon-si (KR)

(72) Inventors: Seunghoon CHOI, Suwon-si (KR); Seongsoo Kim, Suwon-si (KR); Hoyoung Kim, Suwon-si (KR); Yeongbong Park, Suwon-si (KR); Kiho Bae, Suwon-si (KR)

(73) Assignee: SAMSUNG ELECTRONICS CO., LTD., Suwon-si (KR)

(21) Appl. No.: 18/439,271

(22) Filed: Feb. 12, 2024

(30) Foreign Application Priority Data
Jun. 19, 2023 (KR) 10-2023-0078357

(51) Int. Cl. H01L 21/3105; H01L 21/3115; H01L 21/768; H01L 23/528; H01L 29/40

(52) U.S. Cl. CPC H01L 21/31053; H01L 21/31155; H01L 21/76898; H01L 23/5286; H01L 29/401

(57) ABSTRACT

A method of manufacturing a semiconductor device includes forming a first dielectric film on a front-side surface of a substrate that has the front-side surface and a back-side surface, doping a surface of the first dielectric film with impurities to form a doped dielectric film covering at least a portion of the first dielectric film, forming a second dielectric film on the doped dielectric film, and polishing the second dielectric film by a chemical mechanical polishing (CMP) method. The doped dielectric film has a polishing rate less than a polishing rate of each of the first dielectric film and the second dielectric film.

### CROSS-REFERENCE TO RELATED APPLICATION

This application is based on and claims priority under 35 U.S.C. § 119 to Korean Patent Application No. 10-2023-0078357, filed on Jun. 19, 2023, in the Korean Intellectual Property Office, the disclosure of which being incorporated by reference herein in its entirety.

### BACKGROUND

Methods consistent with the present disclosure relate to a method of manufacturing a semiconductor device, and more particularly, to a method of manufacturing a semiconductor device having a back-side power delivery network (BSPDN) structure.

As miniaturization, multifunctionality, and high performance of electronic products are required, high capacity and high integration of semiconductor devices are required. Accordingly, research for efficiently designing wiring structures has been conducted to achieve high integration while securing the functions and operating speeds required in semiconductor devices.

As a planarization process of a film, different processes such as, for example, an etch back process, a reflow process, a chemical mechanical polishing (CMP) process, and the like may be used. The CMP process is widely used as a planarization process for wide-area planarization and high-integration circuits. Various techniques have been studied to control the CMP process.

### SUMMARY

It is an aspect to provide a method of manufacturing a semiconductor device with improved structural stability.

Various embodiments are not limited to the aspect mentioned above, and other aspects and embodiments may be clearly understood by those skilled in the art from the description below.

According to an aspect of one or more embodiments, there is provided a method of manufacturing a semiconductor device, the method comprising forming a first dielectric film on a front-side surface of a substrate that has the front-side surface and a back-side surface; doping a surface of the first dielectric film with impurities to form a doped dielectric film covering at least a portion of the first dielectric film; forming a second dielectric film on the doped dielectric film; and polishing the second dielectric film by a chemical mechanical polishing (CMP) method, wherein the doped dielectric film has a polishing rate less than a polishing rate of each of the first dielectric film and the second dielectric film.

According to another aspect of one or more embodiments, there is provided a method of manufacturing a semiconductor device, the method comprising providing a substrate having a front-side surface and a back-side surface, the substrate including a plurality of fin-type active regions extending in a vertical direction from the front-side surface; forming a plurality of source/drain regions respectively contacting the plurality of fin-type active regions; forming a source/drain contact contacting at least one of the plurality of source/drain regions; forming a via power rail on the front-side surface of the substrate; forming a front-side wiring structure electrically connected to the via power rail and the source/drain contact; forming a first dielectric film on the front-side surface of the substrate, the first dielectric film extending in the vertical direction to surround the front-side wiring structure on the front-side surface of the substrate; doping a surface of the first dielectric film with impurities to form a doped dielectric film that covers at least a portion of the first dielectric film; forming a second dielectric film on the doped dielectric film; and polishing the second dielectric film by a chemical mechanical polishing (CMP) method, wherein the doped dielectric film has a polishing rate less than a polishing rate of each of the first dielectric film and the second dielectric film.

According to yet another aspect of one or more embodiments, there is provided a method of manufacturing a semiconductor device, the method comprising providing a substrate having a front-side surface and a back-side surface, the substrate including a plurality of fin-type active regions that extend in a vertical direction from the front-side surface; forming a plurality of source/drain regions respectively contacting the plurality of fin-type active regions; forming a source/drain contact that contacts at least one of the plurality of source/drain regions; forming a via power rail on the front-side surface of the substrate; forming a front-side wiring structure that electrically connects to the via power rail and the source/drain contact; forming a first dielectric film on the front-side surface of the substrate, the first dielectric film extending in the vertical direction to surround the front-side wiring structure on the front-side surface of the substrate; forming a doped dielectric film that covers at least a portion of a surface of the first dielectric film, the doped dielectric film including carbon (C), boron (B), or silicon (Si), or a combination thereof; forming a second dielectric film on the doped dielectric film; polishing the second dielectric film by a chemical mechanical polishing method; polishing the back-side surface of the substrate; forming a back-side power structure that penetrates the substrate and that electrically connects to the via power rail; forming a back-side wiring structure that connects to the back-side power structure on the back-side surface of the substrate; and forming a back-side insulating layer that surrounds the back-side wiring structure, wherein the doped dielectric film has a polishing rate less than a polishing rate of each of the first dielectric film and the second dielectric film.

### BRIEF DESCRIPTION OF THE DRAWINGS

Various embodiments will be more clearly understood from the following detailed description taken in conjunction with the accompanying drawings, in which:

FIGS. 1A and 1B are schematic diagrams of semiconductor devices according to some embodiments;

FIG. 2 is a cross-sectional view of a semiconductor device according to some embodiments;

FIG. 3 is an enlarged cross-sectional view of an edge region of a semiconductor device according to some embodiments;

FIG. 4 is a flowchart illustrating a method of manufacturing a semiconductor device according to some embodiments; and

FIGS. 5A, 5B, 6A, 6B, 7, 8, 9, 10, 11A, 11B, 12A, 12B, 13A, and 13B are cross-sectional views illustrating a method of manufacturing a semiconductor device in accordance with a process sequence, according to some embodiments, wherein FIG. 5B is an enlarged cross-sectional view of an edge region of FIG. 5A, FIG. 6B is an enlarged cross-sectional view of an edge region of FIG. 6A, FIG. 11B is an enlarged cross-sectional view of an edge region of FIG. 11A, FIG. 12B is an enlarged cross-sectional view of an edge region of FIG. 12A, and FIG. 13B is an enlarged cross-sectional view of an edge region of FIG. 13A.

### DETAILED DESCRIPTION

Hereinafter, various embodiments will be described in detail with reference to the accompanying drawings. The same reference numerals are used for the same components in the drawings, and duplicate descriptions thereof are omitted for conciseness.

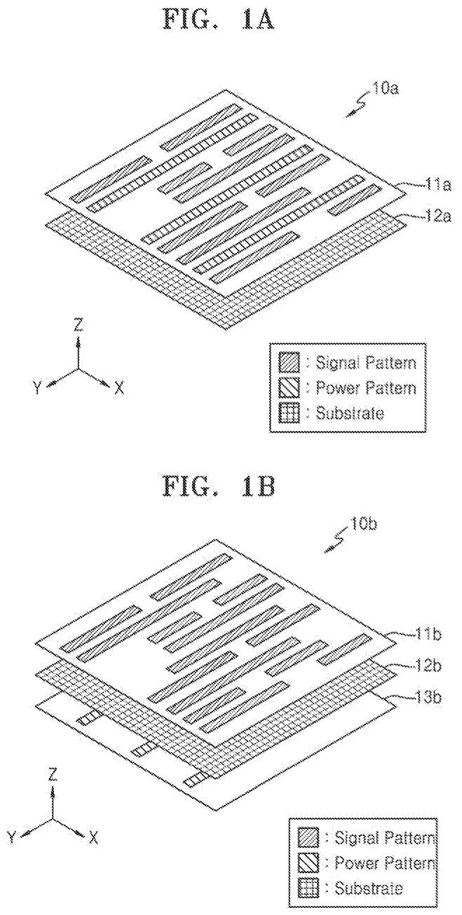

FIGS. 1A and 1B are schematic diagrams of semiconductor devices according to some embodiments.

Referring to FIG. 1A, a semiconductor device 10a may include a wiring layer 11a and a substrate 12a. The substrate 12a may have devices (e.g., transistors) formed thereon.

In this specification, a direction in which the substrate 12a extends may be defined as a first horizontal direction X, a direction crossing the first horizontal direction X may be defined as a second horizontal direction Y, and a direction perpendicular to an upper surface of the substrate 12a may be defined as a vertical direction Z.

The wiring layer 11a may be positioned on the devices, and patterns of conductive material may be formed in the wiring layer 11a. For example, as shown in FIG. 1A, patterns for input signals and/or output signals of the devices (which may be referred to herein as signal patterns) are formed in the wiring layer 11a, and patterns for supplying power to the devices (which may be referred to herein as power patterns) may be formed in the wiring layer 11a.

In some embodiments, the power patterns may be regularly arranged in the wiring layer 11a, and the signal patterns may be arranged in areas in the wiring layer 11a where no power patterns are arranged. For example, as shown in FIG. 1A, the power patterns may extend in parallel in the second horizontal direction Y at regular intervals in the wiring layer 11a, and the signal patterns may extend in the second horizontal direction Y between the power patterns in the wiring layer 11a. However, the arrangement structure of the power patterns and the signal patterns is not limited to that shown FIG. 1A and, in some embodiments, the power patterns and the signal patterns may be arranged in various arrangement structures.

In some embodiments, the wiring layer 11a may include a plurality of layers. For example, the semiconductor device 10a may further include at least one wiring layer between the wiring layer 11a and the substrate 12a, and may further include at least one wiring layer on the wiring layer 11a. The signal patterns or power patterns formed on the adjacent wiring layers 11a may be electrically connected to each other through vias.

A supply voltage, e.g., a positive supply voltage and/or a negative supply voltage (or ground potential), may be applied to the power patterns. For example, the devices may receive the supply voltage applied to a pad on the plurality of wiring layers through the signal patterns or power patterns included in the wiring layer 11a. As such, a structure in which the supply voltage is provided from a front-side surface of the substrate 12a may be referred to as a front-side power delivery network (FSPDN).

However, due to the development of semiconductor processes, the size of the devices formed on the substrate 12a may decrease. Accordingly, it may not be easy to form the signal patterns for routing the input signals and the output signals of the devices and the power patterns for supplying power to the devices on the same wiring layer 11a, and routing congestion of the power patterns may be aggravated by the signal patterns and the power patterns formed on the same wiring layer 11a.

Referring to FIG. 1B, a semiconductor device 10b may include a front-side wiring layer 11b, a substrate 12b, and a back-side wiring layer 13b. The substrate 12b may have devices (e.g., transistors) formed thereon. The front-side wiring layer 11b may be positioned above the devices, and the back-side wiring layer 13b may be positioned below the substrate 12b.

In some embodiments, signal patterns may be regularly arranged on the front-side wiring layer 11b, and power patterns may be regularly arranged on the back-side wiring layer 13b. For example, as shown in FIG. 1B, the signal patterns may extend in the second horizontal direction Y in parallel at regular intervals in the front-side wiring layer 11b, and the power patterns may extend in the second horizontal direction Y in parallel at regular intervals in the back-side wiring layer 13b. However, the arrangement structure of the power patterns and the signal patterns is not limited to that shown in FIG. 1B and, in some embodiments, the power patterns and the signal patterns may be arranged in various arrangement structures. In this specification, the signal patterns arranged in the front-side wiring layer 11b may be referred to as front-side wiring patterns, and the power patterns arranged in the back-side wiring layer 13b may be referred to as back-side wiring patterns.

In some embodiments, the front-side wiring layer 11b or the back-side wiring layer 13b may include a plurality of layers. For example, the semiconductor device 10b may further include at least one front-side wiring layer between the front-side wiring layer 11b and the substrate 12b, and may further include at least one back-side wiring layer between the back-side wiring layer 13b and the substrate 12b. The signal patterns formed on the adjacent front-side wiring layers 11b may be electrically connected to each other through vias, and the power patterns formed on the adjacent back-side wiring layers 13b may be electrically connected to each other through vias. In this specification, a via electrically connecting each of the signal patterns formed on the front-side wiring layer 11b may be referred to as a front-side via, and a via electrically connecting each of the power patterns formed on the back-side wiring layer 13b may be referred to as a back-side via.

The semiconductor device 10b may include a through-silicon via (TSV) to supply power to the devices from the power patterns formed on the back-side wiring layer 13b. Accordingly, the supply voltage may be provided to the devices from the power patterns formed on the back-side wiring layer 13b through the TSV. As such, a structure in which the supply voltage is provided from a back-side surface of the substrate 12b may be referred to as a back-side power delivery network (BSPDN). In this specification, the TSV may be referred to as a back-side power structure.

As shown in FIG. 1B, signal patterns may be formed in the front-side wiring layer 11b, and power patterns may be formed in the back-side wiring layer 13b. Accordingly, the power patterns may be omitted in the front-side wiring layer 11b, and the signal patterns may be arranged in areas where the power patterns are omitted. Accordingly, the semiconductor device 10b of FIG. 1B may provide higher routability than the semiconductor device 10a of FIG. 1A.

As shown in FIG. 1B, it is assumed that a semiconductor device according to some embodiments described below includes a BSPDN structure in which a supply voltage is provided from a back-side surface of a substrate.

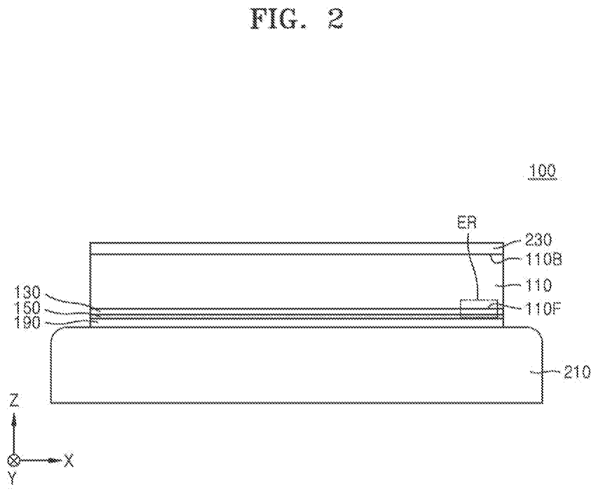

FIG. 2 is a cross-sectional view of a semiconductor device according to some embodiments.

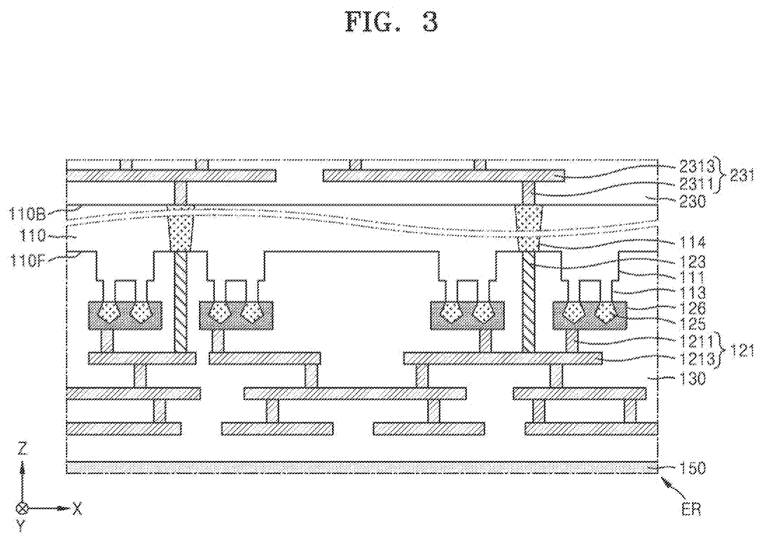

FIG. 3 is an enlarged cross-sectional view of an edge region of a semiconductor device according to some embodiments.

Referring to FIGS. 2 and 3, a semiconductor device 100 may include a substrate 110, a first dielectric film 130, a doped dielectric film 150, a bonding layer 190, a carrier substrate 210, and a back-side insulating film 230. The substrate 110 may be coupled to the carrier substrate 210 with the first dielectric film 130, the doped dielectric film 150, and the bonding layer 190 positioned therebetween such that a front-side surface 110F of the substrate 110 faces the carrier substrate 210. The substrate 110 may be coupled to the back-side insulating film 230 such that a back-side surface 110B of the substrate 110 faces the back-side insulating film 230.

The substrate 110 may include a semiconductor such as Si or Ge, or a compound semiconductor such as SiGe, SiC, GaAs, InAs, InGaAs, or InP. The terms “SiGe”, “SiC”, “GaAs”, “InAs”, “InGaAs”, and “InP” used in this specification refer to materials made of elements included in each term, and are not chemical formulas representing stoichiometric relationships. The substrate 110 may include a conductive region, for example, a well that is doped with impurities or a structure that is doped with impurities.

The first dielectric film 130 may be disposed on the front-side surface 110F of the substrate 110. In some embodiments, the first dielectric film 130 may include a plurality of dielectric films sequentially stacked between the substrate 110 and the doped dielectric film 150. The first dielectric film 130 may have a thickness within a range of about 400 nanometers to about 600 nanometers in the vertical direction Z. That is, the first dielectric film 130 may have a thickness in the vertical direction Z from the front-side surface 110F of the substrate 110. The thickness of the first dielectric film 130 in the vertical direction Z may be a minimum thickness that is required to protect a wiring structure inside the first dielectric film 130. In some embodiments, the first dielectric film 130 may include oxide and/or nitride. For example, the first dielectric film 130 may include silicon oxide and/or silicon nitride. In some embodiments, the first dielectric film 130 may include an insulating material of photo imageable dielectric (PID) material capable of photolithography processing. For example, in some embodiments, the first dielectric film 130 may include photosensitive polyimide (PSPI).

A plurality of individual device regions 111 and a plurality of fin-type active regions 113 protruding from the substrate 110 toward the first dielectric film 130 may be arranged on the front-side surface 110F of the substrate 110. In some embodiments, the plurality of individual device regions 111 may include regions doped with a P-type dopant or an N-type dopant. The plurality of individual device regions 111 and the plurality of fin-type active regions 113 may be spaced apart from each other in a first horizontal direction X, and may extend in the second horizontal direction Y. The plurality of fin-type active regions 113 may extend from the individual device regions 111 in the vertical direction Z, and may extend in parallel.

A plurality of source/drain regions 125 may be arranged on the plurality of fin-type active regions 113, respectively. In some embodiments, a pair of adjacent source/drain regions 125 (i.e., two source/drain regions 125 that are adjacent to each other) selected from among the plurality of source/drain regions 125 may contact a pair of adjacent fin-type active regions 113 (i.e., two fin-type active regions 113 that are adjacent to each other) selected from among the plurality of fin-type active regions 113, respectively. The pair of adjacent source/drain regions 125 selected from among the plurality of source/drain regions 125 may be electrically connected to a source/drain contact 126 in common, but embodiments are not limited thereto. In some embodiments, one source/drain region 125 may be electrically connected to one source/drain contact 126. For example, in some embodiment, each of the plurality of source/drain regions 125 may be provided with a source/drain contact 126 in a one-to-one arrangement.

A plurality of source/drain contacts 126 may be arranged to be electrically connected to the plurality of source/drain regions 125. The source/drain contacts 126 may be formed to at least partially surround the source/drain regions 125. In some embodiments, the source/drain contact 126 may surround the pair of source/drain regions 125 selected from among the plurality of source/drain regions 125, as illustrated by way of example in FIG. 3. The source/drain contacts 126 may be spaced apart from each other in the first horizontal direction X with a via power rail 123 positioned therebetween. The source/drain contacts 126 may be insulated by the first dielectric film 130. The source/drain contacts 126 may include molybdenum (Mo), copper (Cu), tungsten (W), cobalt (Co), ruthenium (Ru), manganese (Mn), titanium (Ti), tantalum (Ta), or aluminum (Al), or a combination thereof, or an alloy thereof, but embodiments are not limited thereto.

In some embodiments, one source/drain contact 126 selected from among the plurality of source/drain contacts 126 may be connected to the via power rail 123 through a front-side wiring structure 121 at a position spaced apart from the via power rail 123 in the first horizontal direction X. In some embodiments, one source/drain contact 126 from a pair of adjacent source/drain contacts 126 (i.e., two source/drain contacts 126 that are adjacent to each other) may be connected to the via power rail 123 that is between the pair of adjacent source/drain contacts 126 by the front-side wiring structure 121 (see, e.g., left hand side of FIG. 3). In some embodiments, both source/drain contact 126 from a pair of adjacent source/drain contacts 126 (i.e., two source/drain contacts 126 that are adjacent to each other) may be connected to the via power rail 123 that is between the pair of adjacent source/drain contacts 126 by the front-side wiring structure 121 (see, e.g., right hand side of FIG. 3).

Although not shown, a plurality of gate lines may be formed on the plurality of fin-type active regions 113 at positions spaced apart from the plurality of source/drain regions 125 in the second horizontal direction Y. The plurality of gate lines may extend in the first horizontal direction X.

Although not shown, a plurality of transistors may be formed in regions where the plurality of fin-type active regions 113 intersect with the plurality of gate lines in the second horizontal direction Y. In some embodiments, the plurality of transistors may include a tunneling field-effect transistor (TFET), a transistor including nanowires, a transistor including nanosheets, a vertical FET (VFET), a complementary FET (CFET), or a three-dimensional (3D) transistor.

A plurality of channel regions may be located in regions where the plurality of fin-type active regions 113 intersect with the plurality of gate lines in the second horizontal direction Y. The plurality of gate lines may surround the plurality of channel regions. In some embodiments, the plurality of channel regions may include a plurality of nanosheet stacks. In this specification, a “nanosheet” refers to a conductive structure having a cross section substantially perpendicular to a direction in which current flows, and may include nanowires.

The front-side wiring structure 121 may be arranged on the source/drain contact 126. The front-side wiring structure 121 may include a structure formed through a back end of line (BEOL) process. The front-side wiring structure 121 may include a plurality of front-side wiring patterns 1213 and a plurality of front-side vias 1211. The front-side wiring patterns 1213 and the front-side vias 1211 may be covered in the first dielectric film 130. The front-side wiring patterns 1213 may extend in the first horizontal direction X or the second horizontal direction Y within the first dielectric film 130. In addition, the plurality of front-side wiring patterns 1213 may be positioned at different levels in the vertical direction Z within the first dielectric film 130 to form a multilayer wiring structure. The plurality of front-side wiring patterns 1213 are illustrated as having a three-layer structure in FIG. 3, but this three-layer structure is exemplary and, in some embodiments, the plurality of front-side wiring patterns 1213 may have a two-layer structure or a four or more layer structure.

Among the plurality of front-side wiring patterns 1213, a portion of the front-side wiring patterns 1213 closest to the source/drain contacts 126 may be directly connected to the via power rails 123. The others of the front-side wiring patterns 1213 closest to the source/drain contacts 126 may be connected to the via power rails 123 with the front-side wiring patterns 1213 and the front-side wiring vias 1211, both positioned therebetween.

A portion of the plurality of front-side vias 1211 extend in the vertical direction Z between the plurality of front-side wiring patterns 1213 located at different levels, and may electrically connect the plurality of front-side wiring patterns 1213 located at different levels. Among the plurality of front-side vias 1211, the front-side vias 1211 closest to the substrate 110 may be directly connected to the source/drain contacts 126.

The front-side wiring structure 121 may include metals such as Cu, Al, W, Ti, Ta, indium (In), Mo, Mn, Co, tin (Sn), nickel (Ni), magnesium (Mg), rhenium (Re), beryllium (Be), gallium (Ga), or Ru, or alloys thereof, but embodiments are not limited thereto.

The via power rails 123 may extend in the vertical direction Z between the plurality of individual device regions 111, between pairs of adjacent fin-type active regions 113 (i.e., two fin-type active regions 113 that are adjacent to each other) selected from among the plurality of fin-type active regions 113, and between pairs of source/drain regions 125 arranged on the pairs of fin-type active regions 113. The via power rails 123 may extend in the vertical direction Z from the front-side surface 110F of the substrate 110 and contact the front-side wiring layers 1213 closest to the substrate 110.

In some embodiments, the via power rail 123 may include a metal wiring layer and a conductive barrier layer surrounding the metal wiring layer. The metal wiring layer may include Ru, Co, or W, or a combination thereof. The conductive barrier layer may include Ti, TiN, Ta, or TaN, or a combination thereof. Sidewalls of the via power rail 123 are not shown for clarity and conciseness, but may be surrounded by insulating spacers. The insulating spacers may include a silicon oxide film, a silicon oxynitride film, or a silicon nitride film, or a combination thereof.

The back-side surface 110B of the substrate 110 may be covered with the back-side insulating film 230. The back-side insulating film 230 may include a silicon oxide film, a silicon nitride film, a silicon carbide film, or a low dielectric film, or a combination thereof. The low dielectric film may include fluorine-doped silicon oxide, organosilicate glass, carbon-doped oxide, porous silicon oxide, porous organosilicate glass, spin-on organic polymeric dielectric, or spin-on silicon based polymeric dielectric, or a combination thereof, but embodiments are not limited thereto.

A back-side power structure 114 may penetrate the substrate 110 in the vertical direction Z and may be arranged at a position overlapping the via power rail 123 in the vertical direction Z. In some embodiments, the back-side power structure 114 may have a tapered shape, and a width of the back-side power structure 114 in the first horizontal direction X may increase as the back-side power structure 114 is closer to the back-side surface 110B of the substrate 110. The back-side power structure 114 may include a metal wiring layer and a conductive barrier layer surrounding the metal wiring layer. The detailed configurations and functions of the metal wiring layer and the conductive barrier layer constituting the back-side power structure 114 are substantially the same as those described above for the metal wiring layer and the conductive barrier layer constituting the via power rail 123 and thus a detailed description thereof is omitted for conciseness. Sidewalls of the back-side power structure 114 are not shown, but may be surrounded by insulating liners. The insulating liners may include a silicon oxide film, a silicon oxynitride film, or a silicon nitride film, or a combination thereof. In some embodiments, the insulating liners may have a single film structure or a structure in which two or more films are stacked.

The back-side power structure 114 may be spaced apart from the pairs of source/drain regions 125 on sides of the via power rail 123 and the pairs of fin-type active regions 113 on sides of the via power rail 123.

The back-side power structure 114 may be connected to a back-side wiring structure 231 on the back-side surface 110B of the substrate 110. The back-side wiring structure 231 may include a structure formed through the BEOL process. In some embodiments, the back-side wiring structure 231 may include a plurality of back-side wiring patterns 2313 and a plurality of back-side vias 2311. The back-side wiring patterns 2313 and the back-side vias 2311 may be covered in the back-side insulating film 230. The back-side wiring patterns 2313 may extend in the first horizontal direction X or the second horizontal direction Y within the back-side insulating film 230. In some embodiments, the plurality of back-side wiring patterns 2313 may be positioned at different levels in the vertical direction Z within the back-side insulating film 230 to form a multilayer wiring structure. The plurality of back-side wiring patterns 2313 are illustrated as having a single layer structure in FIG. 3, but this single layer structure is exemplary and, in some embodiments, the plurality of back-side wiring patterns 2313 may have a two or more layer structure.

A portion of the plurality of back-side vias 2311 may extend in the vertical direction Z between the plurality of back-side wiring patterns 2313 positioned at different levels, and may connect the plurality of back-side wiring patterns 2313 positioned at different levels. The back-side vias 2311 closest to the substrate 110 among the plurality of back-side vias 2311 may be connected to the back-side power structures 114.

The back-side wiring structure 231 may include metals such as Cu, Al, W, Ti, Ta, In, Mo, Mn, Co, Sn, Ni, Mg, Re, Be, Ga, or Ru, or alloys thereof, but embodiments are not limited thereto.

The doped dielectric film 150 may be disposed on the first dielectric film 130. In some embodiments, the doped dielectric film 150 may be formed on a surface of the first dielectric film 130 by doping the first dielectric film 130 with impurities. In some embodiments, the doped dielectric film 150 may be formed in the surface of the first dielectric film 130 by doping the impurities into the surface of the first dielectric film 130. The impurity doping may be performed through an ion implantation process or a plasma process. The doped dielectric film 150 may be formed to have an impurity concentration higher than an impurity concentration of an impurity region included in the first dielectric film 130 or the substrate 110. The impurities used for doping the doped dielectric film 150 may include a material capable of hydrophobizing the first dielectric film 130. For example, the impurities may include carbon (C), boron (B), or silicon (Si), or a combination thereof.

In some embodiments, the doped dielectric film 150 may include a composition in which the composition of the first dielectric film 130 is doped with C, B, or Si, or a combination thereof. For example, when the first dielectric film 130 includes silicon oxide, the doped dielectric film 150 may include a composition in which silicon oxide is doped with C, B, or Si, or a combination thereof. The doped dielectric film 150 may include a composition of SiOₓC_{y}N_{z}, where x may be a number greater than 0 but not more than 3, y may be a number greater than 0 but not more than 3, and z may be a number greater than 0 but not more than 3.

The concentration of doped impurities in the doped dielectric film 150 may vary depending on process conditions during an impurity doping process. For example, when an edge region of the first dielectric film 130 is defined as extending from the central portion of the first dielectric film 130 in the first horizontal direction X and the second horizontal direction Y, to intensively protect the edge region of the first dielectric film 130 from being removed, the impurity doping process may be adjusted so that an amount of impurities doped in the edge region of the first dielectric film 130 is greater than an amount of impurities doped in the central portion of the first dielectric film 130. In an etching process under the corresponding conditions, a portion of the doped dielectric film 150 formed by doping the edge region of the first dielectric film 130 may be etched at a different etching rate from a portion of the doped dielectric film 150 formed by doping the central portion of the first dielectric film 130. In some embodiments, the concentration of doped impurities in the doped dielectric film 150 may vary in the vertical direction Z within the doped dielectric film 150. For example, in a process of implanting impurities in a direction perpendicular to an upper surface of the first dielectric film 130, the concentration of the elements used for doping in the doped dielectric film 150 may decrease toward the first dielectric film 130. That is, the concentration of the elements used for doping may decrease as a distance from the first dielectric film 130 in the vertical direction Z decreases.

In a chemical mechanical polishing (CMP) process, a polishing object to undergo polishing may be mounted in a polishing device, and a chemical mechanical polishing slurry composition containing abrasive particles may be provided between the polishing object and a polishing pad. A surface of the polishing object may be planarized by rotating the polishing object while in contact with the polishing pad. That is, the chemical mechanical polishing process is a process of mechanically polishing the surface of the polishing object by mechanically rubbing the surface of the polishing object with abrasive particles included in the chemical mechanical polishing slurry composition and surface protrusions of the polishing pad, and chemically removing the surface of the polishing object by chemically reacting the surface of the polishing object with chemical components included in the chemical mechanical polishing slurry composition.

During the impurity doping process, a polishing rate of the doped dielectric film 150 in the chemical mechanical polishing process may be reduced compared to that of the first dielectric film 130 in which impurities are not implanted. The chemical mechanical polishing slurry composition used in the chemical mechanical polishing process may include a large amount of deionized water (DIW). Since the doped dielectric film 150 is more hydrophobic than the first dielectric film 130 in which impurities are not implanted, with respect to the chemical mechanical polishing slurry composition used in the chemical mechanical polishing process, a selectivity of the doped dielectric film 150 may be less than a selectivity of the first dielectric film 130, and a polishing rate of the doped dielectric film 150 may be less than a polishing rate of the first dielectric film 130.

Referring again to FIG. 2, the bonding layer 190 may be disposed on the doped dielectric film 150. The bonding layer 190 may extend in the first horizontal direction X and the second horizontal direction Y along the doped dielectric film 150. The bonding layer 190 may include a silicon oxide film, a silicon nitride film, or a silicon carbonitride film. Although not shown, depending on a bonding process method with the carrier substrate 210, an adhesive layer including an adhesive material for bonding with the carrier substrate 210 may be further provided on an upper surface of the bonding layer 190.

The carrier substrate 210 may be disposed on the bonding layer 190. The carrier substrate 210 may be a substrate provided for performing a back grinding process on the back-side surface 110B of the substrate 110. A thickness of the carrier substrate 210 in the vertical direction Z may be greater than a thickness of the substrate 110 in the vertical direction Z. A diameter of the carrier substrate 210 in the first horizontal direction X or the second horizontal direction Y may be greater than a diameter of the substrate 110 in the first horizontal direction X or the second horizontal direction Y. Accordingly, a portion of an upper surface of the carrier substrate 210 excluding a portion thereof to which the substrate 110 is attached may be exposed to the outside of the substrate 110, as illustrated by way of example in FIG. 2. The carrier substrate 210 may be removed in a subsequent semiconductor packaging process. The carrier substrate 210 may include silicon, glass, ceramic, organic material, or plastic.

Although not shown, a connection member connected to the back-side wiring structure 231 may be disposed on the back-side insulating film 230 of FIG. 2, and the connection member may include conductive bumps and bump pads. The conductive bumps may include solder bumps, and the bump pads may include under bump metals (UBM).

The power input to the connection member may be sequentially transmitted to the back-side power structures 114 through the back-side wiring structures 231, transmitted to the via power rails 123 through the back-side power structures 114, transmitted to the front-side wiring patterns 1213 in contact with the via power rails 123 through the via power rails 123, transmitted to the source/drain contacts 126 through the front-side wiring vias 1211, and transmitted to the individual device regions 111 through the source/drain contacts 126. The power transmitted to the front-side wiring structure patterns 1213 in contact with the via power rails 123 may be transmitted to the front-side wiring structure patterns 1213 positioned at different levels in the vertical direction Z through the front-side wiring vias 1211. As such, the semiconductor device 100 may include a BSPDN structure in which a supply voltage is provided from the back-side surface 110B of the substrate 110.

As a comparative example, a case according to the related art in which a doping process for forming the doped dielectric film 150 on the first dielectric film 130 is omitted is described. After forming the first dielectric film 130 on the substrate 110 within a range of about 1300 nanometers to about 1500 nanometers, and before bonding the carrier substrate 210 thereto, an edge trimming process of etching a portion of the substrate 110 and a portion of the first dielectric film 130 may be performed on a bevel region. After performing the edge trimming process, a chemical mechanical polishing process for reducing surface roughness of a dielectric film is performed. An edge region of the upper surface of the first dielectric film 130 adjacent to the bevel region may be over-polished, and the upper surface of the first dielectric film 130 may have an uneven profile. When bonding the first dielectric film 130 to the carrier substrate 210, a bonding defect may occur between the first dielectric film 130 and the carrier substrate 210 due to the uneven profile of the upper surface of the first dielectric film 130, and during a subsequent process of polishing the back-side surface 110B of the substrate 110, a structural defect in which the substrate 110 is bent may occur due to the bonding defect between the first dielectric film 130 and the carrier substrate 210.

By contrast, according to some embodiments, after forming the first dielectric film 130 having a target thickness on the substrate 110, the ion implantation process is performed to form the doped dielectric film 150 in the surface of the first dielectric film 130. In the chemical mechanical polishing process, since the doped dielectric film 150 has a lower selectivity and a lower polishing rate than the first dielectric film 130, the doped dielectric film 150 may be used as an etch stop film for the first dielectric film 130.

Therefore, since the edge region of the upper surface of the first dielectric film 130 adjacent to the bevel region is protected with the doped dielectric film 150, thereby preventing the edge region of the upper surface of the first dielectric film 130 adjacent to the bevel region from being over-polished, the upper surface of the doped dielectric film 150 may have a flat profile. Thus, a bonding defect in a subsequent bonding process with the carrier substrate 210 may be prevented, and structural stability of the semiconductor device may be improved.

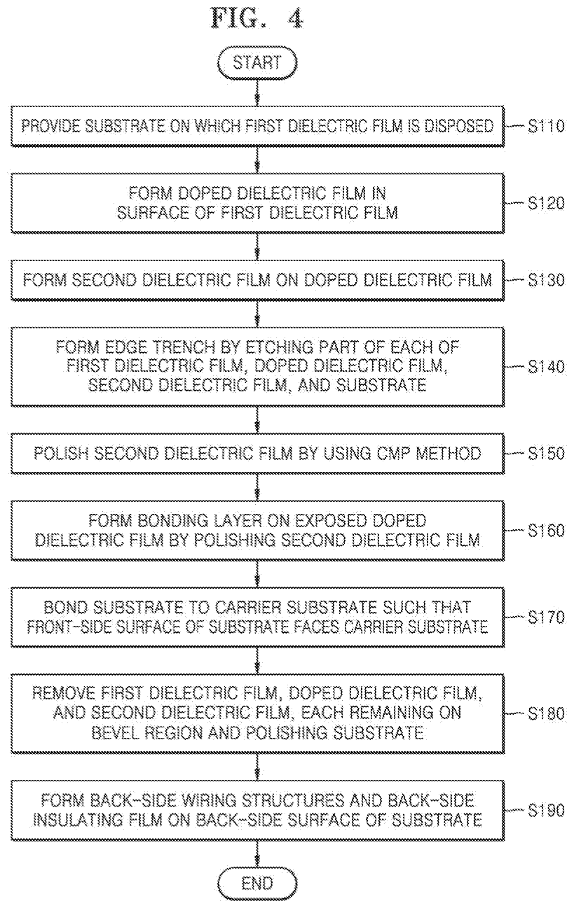

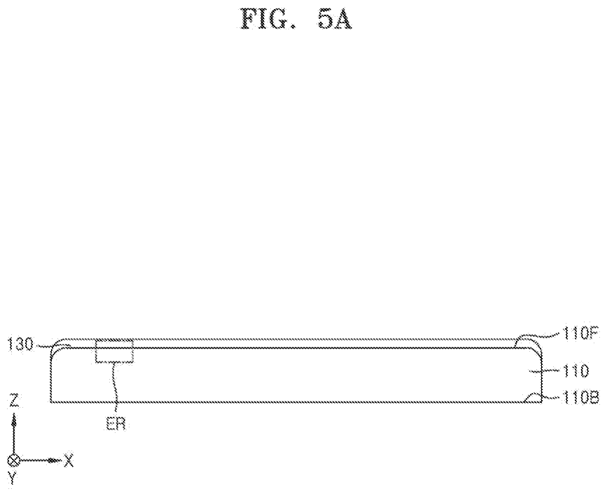

FIG. 4 is a flowchart illustrating a method of manufacturing a semiconductor device according to some embodiments.

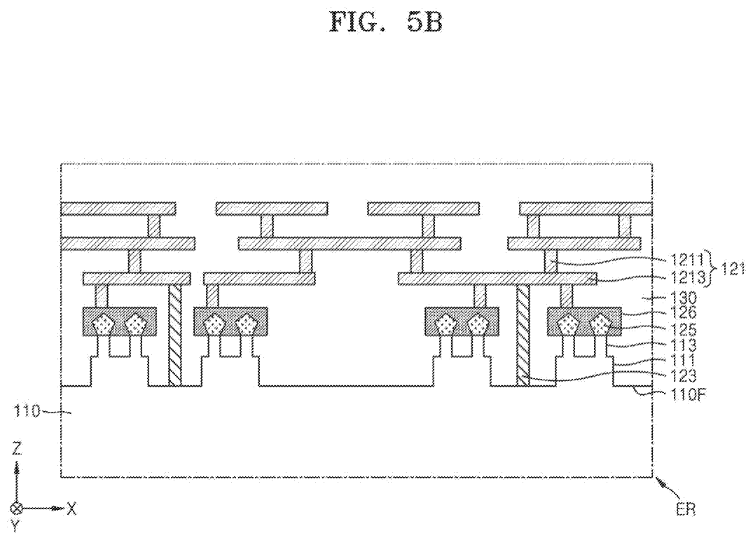

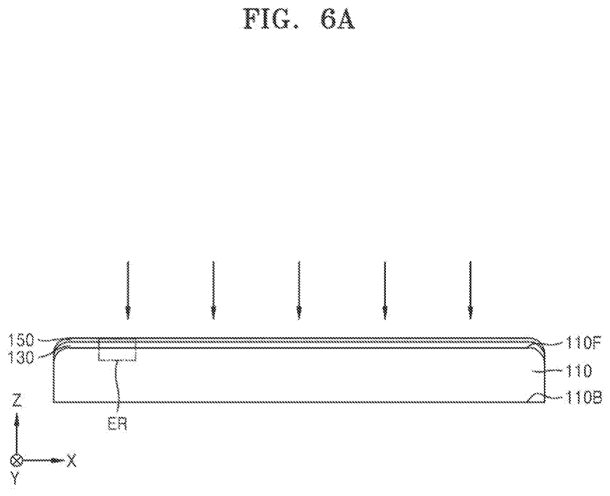

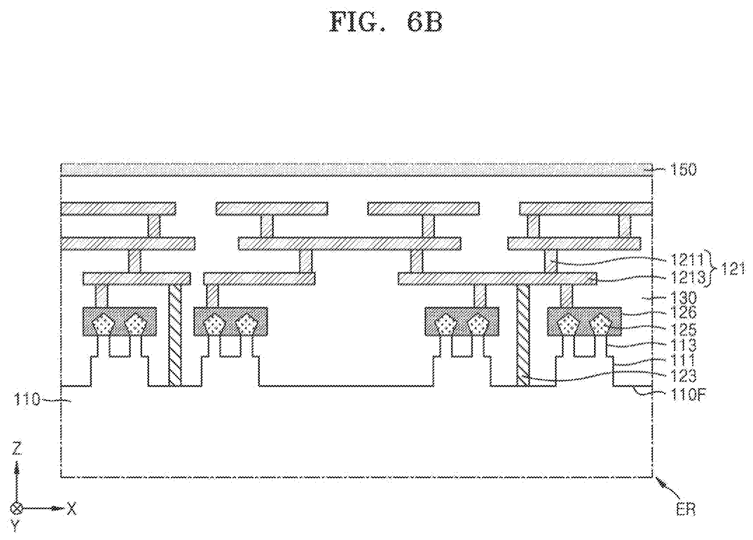

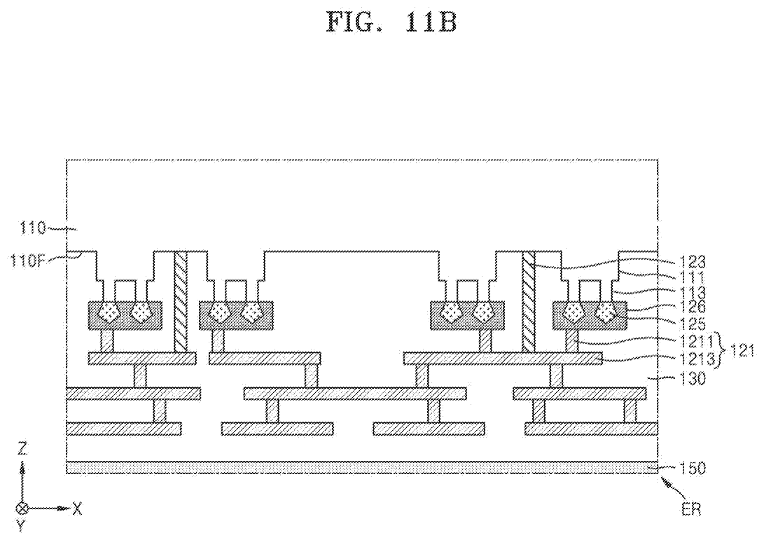

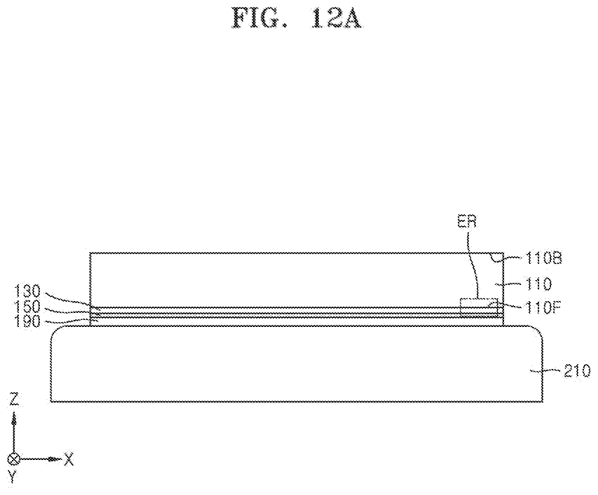

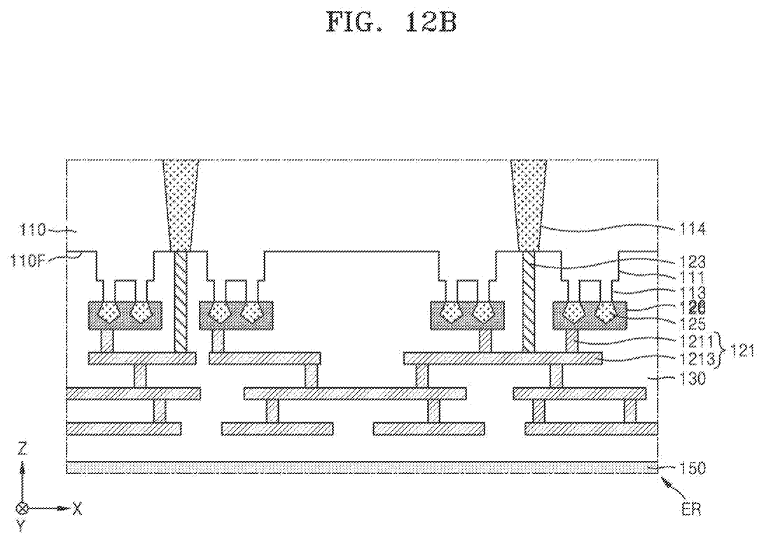

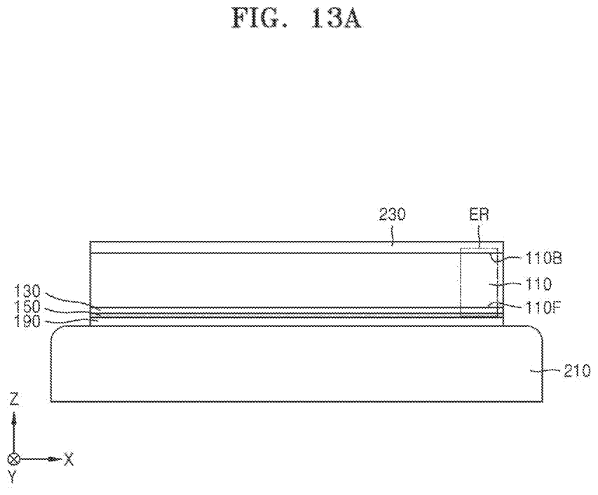

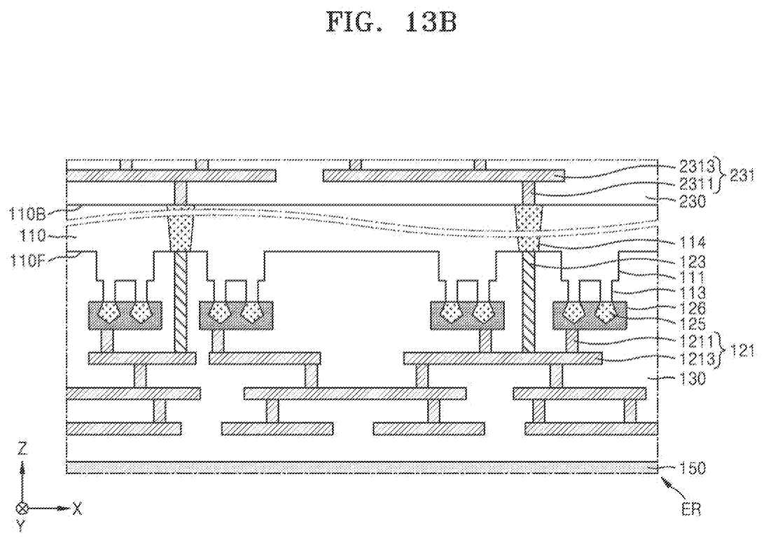

FIGS. 5A, 5B, 6A, 6B, 7, 8, 9, 10, 11A, 11B, 12A, 23B, 13A, and 13B are cross-sectional views illustrating a method of manufacturing a semiconductor device in accordance with a process sequence, according to some embodiments, where FIG. 5B is an enlarged cross-sectional view of an edge region of FIG. 5A, FIG. 6B is an enlarged cross-sectional view of an edge region of FIG. 6A, FIG. 11B is an enlarged cross-sectional view of an edge region of FIG. 11A, FIG. 12B is an enlarged cross-sectional view of an edge region of FIG. 12A, and FIG. 13B is an enlarged cross-sectional view of an edge region of FIG. 13A.

Referring to FIGS. 4, 5A, and 5B together, the method of manufacturing a semiconductor device according to an embodiment may include providing the substrate 110 on which the first dielectric film 130 is disposed (S110).

In some embodiments, the providing the substrate 110 on which the first dielectric film 130 is disposed (S110) may include forming the individual device regions 111 and the fin-type active regions 113 in the substrate 110, forming the source/drain contacts 126 and the source/drain regions 125, forming the front-side wiring structures 121, and forming the first dielectric film 130 on the substrate 110.

The forming of the individual device regions 111 and the fin-type active regions 113 in the substrate 110, forming of the source/drain contacts 126 and the source/drain regions 125, and the forming of the first dielectric film 130 on the substrate 110 may include a front end of line (FEOL) process and a middle of line (MOL) process, and the forming of the front-side wiring structures 121 may include the BEOL process. In some embodiments, the FEOL process may include an isolation operation, a N-type well or a P-type well formation operation, a gate oxidation operation, a source region and drain region formation operation, and a dielectric film formation operation. In some embodiments, the BEOL process may include a contact formation operation, a wiring pattern formation operation, a dielectric film formation operation, a via hole formation operation, a via plug formation operation, and a passivation formation operation.

Referring to FIGS. 4, 6A, and 6B together, the method of manufacturing a semiconductor device according to an embodiment may include forming the doped dielectric film 150 on the surface of the first dielectric film 130 (S120).

Specifically, the doped dielectric film 150 may be formed on the surface of the first dielectric film 130 by performing impurity doping in the surface of the first dielectric film 130. The impurity doping may be performed through the ion implantation process or plasma process. The impurity doping may be performed by implanting impurities into the upper surface of the first dielectric film 130 in the vertical direction Z. In some embodiments, the impurities may include a material capable of hydrophobizing the surface of the first dielectric film 130, and may include, for example, C, B, or Si, or a combination thereof. That is, the doped dielectric film 150 may have a composition including C, B, or Si, or a combination thereof in the composition of the first dielectric film 130. The doped dielectric film 150 may include a composition of SiOₓC_{y}N_{z} and x may be a number greater than 0 but not more than 3,y may be a number greater than 0 but not more than 3, and z may be a number greater than 0but not more than 3. The doped dielectric film 150 may be more hydrophobic than the first dielectric film 130 in which impurities are not implanted.

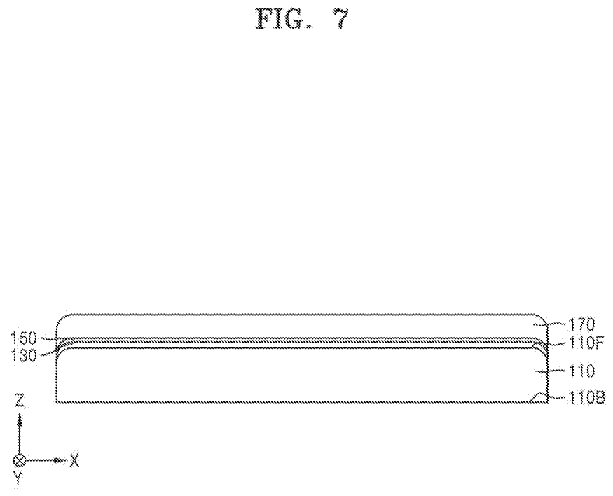

Referring to FIGS. 4 and 7 together, the method of manufacturing a semiconductor device according to an embodiment may include forming a second dielectric film 170 on the doped dielectric film 150 (S130).

The second dielectric film 170 may have a composition similar to a composition of the first dielectric film 130. In some embodiments, the second dielectric film 170 may include oxide and/or nitride. For example, the second dielectric film 170 may include silicon oxide and/or silicon nitride. In some embodiments, the second dielectric film 170 may include the insulating material of PID material capable of undergoing a photolithography process. For example, the second dielectric film 170 may include PSPI. The doped dielectric film 150 may be more hydrophobic than the second dielectric film 170 in which impurities are not implanted.

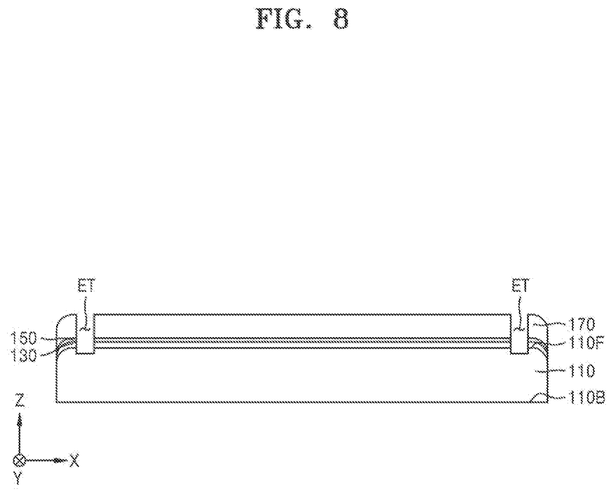

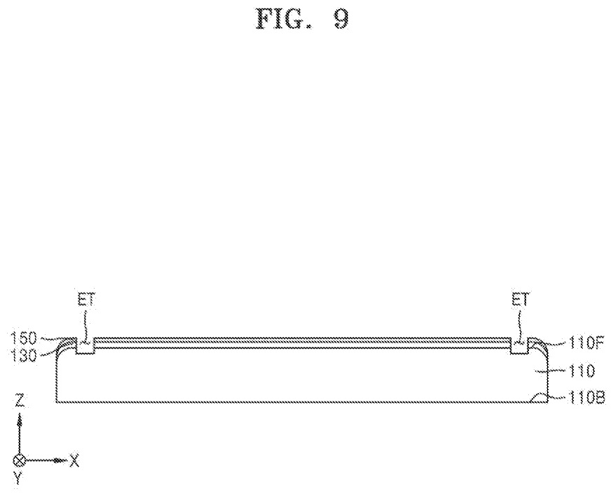

Referring to FIGS. 4 and 8 together, the method of manufacturing a semiconductor device according to an embodiment may include forming an edge trench ET by etching a portion of each of the first dielectric film 130, the doped dielectric film 150, the second dielectric film 170, and the substrate 110 (S140). The edge trench ET may be formed by etching a portion of each of the first dielectric film 130, the doped dielectric film 150, the second dielectric film 170, and the substrate 110.

The portion of the substrate 110 may be exposed from a bottom surface of the edge trench ET. The portions of the first dielectric film 130, the doped dielectric film 150, and the second dielectric film 170 may be exposed from sidewalls of the edge trench ET.

In some embodiments, the edge trench ET may be formed by an edge trimming process of etching a portion of each of the substrate 110, the first dielectric film 130, the doped dielectric film 150, and the second dielectric film 170 in the vertical direction Z by using an edge trimming device (not shown). In some embodiments, the edge trimming device (not shown) may rotate along the central axis of the substrate 110 to etch a portion of each of the substrate 110, the first dielectric film 130, the doped dielectric film 150, and the second dielectric film 170, each on the bevel region.

A width of the edge trench ET in the first horizontal direction X or a depth of the edge trench ET in the vertical direction Z may vary depending on conditions of the edge trimming process. The first dielectric film 130, the doped dielectric film 150, and the second dielectric film 170, each remaining on the bevel region may vary depending on conditions of the edge trimming process, and in some embodiments, the first dielectric film 130, the doped dielectric film 150, and the second dielectric film 170 may not remain on the bevel region. For example, the first dielectric film 130, the doped dielectric film 150, and the second dielectric film 170, each surrounding an outer portion of the edge trench ET, may not remain on the bevel region.

Referring to FIGS. 4 and 9 together, the method of manufacturing a semiconductor device according to an embodiment may include polishing the second dielectric film 170 by using a chemical mechanical polishing method (S150). To perform chemical mechanical polishing, the substrate 110 on which the second dielectric film 170 is disposed may be immersed in a chemical mechanical polishing slurry composition or cleaned. The chemical mechanical polishing slurry composition used in the chemical mechanical polishing process may contain a large amount of DIW.

As described above, since the second dielectric film 170 includes a composition similar to the composition of the first dielectric film 130, the doped dielectric film 150 may be more hydrophobic than the second dielectric film 170 in which impurities are not implanted, and with respect to the chemical mechanical polishing slurry composition used in the chemical mechanical polishing process, the selectivity of the doped dielectric film 150 may be less than the selectivity of the second dielectric film 170, and the polishing rate of the doped dielectric film 150 may be less than the polishing rate of the second dielectric film 170.

With respect to the chemical mechanical polishing slurry composition used in the chemical mechanical polishing process, the selectivity of the doped dielectric film 150 may be less than the selectivity of the first dielectric film 130, and the polishing rate of the doped dielectric film 150 may be less than the polishing rate of the first dielectric film 130. Accordingly, during the chemical mechanical polishing process, the second dielectric film 170 may be etched before the doped dielectric film 150, and the doped dielectric film 150 may be used as an etch stop film for the first dielectric film 130.

As a comparative example, a case according to the related art in which a doping process for forming the doped dielectric film 150 on the first dielectric film 130 is omitted is described. After forming the first dielectric film 130 on the substrate 110 within a range of about 1300 nanometers to about 1500 nanometers, and before bonding the carrier substrate 210 thereto, the edge trimming process of etching a portion of the substrate 110 and a portion of the first dielectric film 130 may be performed on the bevel region. Through the edge trimming process, the edge trench ET may be formed. After performing the edge trimming process, a chemical mechanical polishing process for reducing surface roughness of the first dielectric film 130 is performed. An edge region of the first dielectric film 130 adjacent to the edge trench

ET may be over-polished, and the upper surface of the first dielectric film 130 may have an uneven profile. When bonding the first dielectric film 130 to the carrier substrate 210, a bonding defect may occur between the first dielectric film 130 and the carrier substrate 210 due to the uneven profile of the upper surface of the first dielectric film 130, and during a subsequent process of polishing the back-side surface 110B of the substrate 110, a structural defect in which the substrate 110 is bent may occur due to the bonding defect between the first dielectric film 130 and the carrier substrate 210.

By contrast, according to some embodiments, after forming the first dielectric film 130 having a target thickness on the substrate 110, the ion implantation process is performed to form the doped dielectric film 150 in the surface of the first dielectric film 130. In the chemical mechanical polishing process, since the doped dielectric film 150 has a lower selectivity and a lower polishing rate than the first dielectric film 130, the doped dielectric film 150 may be used as an etch stop film for the first dielectric film 130.

Therefore, since the edge region of the upper surface of the first dielectric film 130 adjacent to the edge trench ET is protected with the doped dielectric film 150, thereby preventing the edge region of the upper surface of the first dielectric film 130 adjacent to the edge trench ET from being over-polished, the upper surface of the doped dielectric film 150 may have a flat profile. Thus, a bonding defect in a subsequent bonding process with the carrier substrate 210 may be prevented, and structural stability of the semiconductor device may be improved.

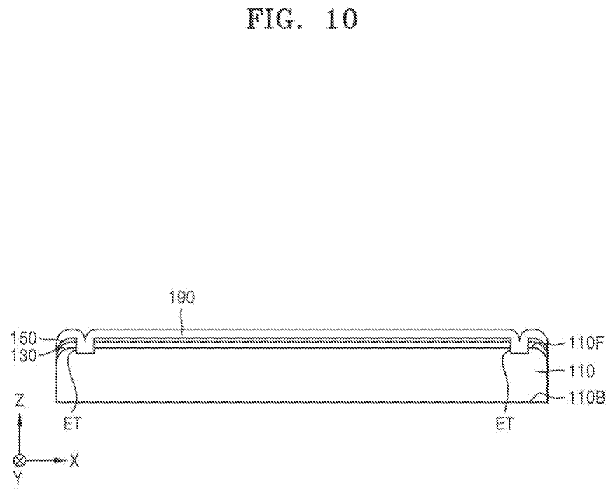

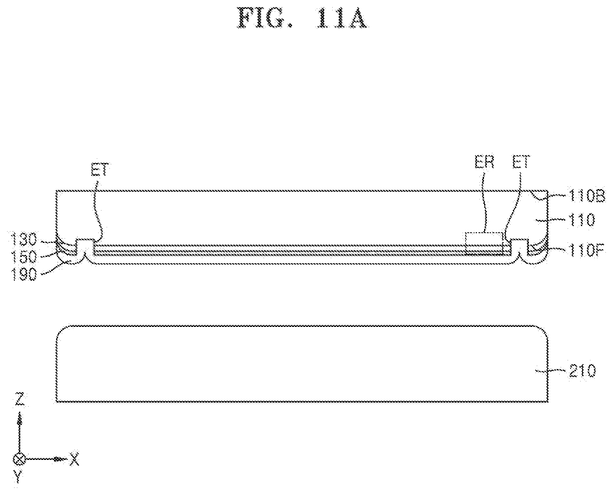

Referring to FIGS. 4 and 10 together, the method of manufacturing a semiconductor device according to an embodiment may include forming a bonding layer 190 on the exposed doped dielectric film 150 by polishing the second dielectric film 170 (S160). The bonding layer 190 may be formed along an upper surface of the product formed by polishing the second dielectric film 170 of FIG. 9. Since the product formed by polishing the second dielectric film 170 of FIG. 9 includes the edge trench ET on the upper surface of the product, the bonding layer 190 may partially fill the edge trench ET.

Referring to FIGS. 4, 11A, and 11B together, the method of manufacturing a semiconductor device according to an embodiment may include bonding the substrate 110 to the carrier substrate 210 such that the front-side surface 110F of the substrate 110 faces the carrier substrate 210 (S170).

In some embodiments, the operation of bonding the substrate 110 to the carrier substrate 210 such that the front-side surface 110F of the substrate 110 faces the carrier substrate 210 (S170) may be performed by performing a silicon direct bonding (SDB) process. The SDB process may be a bonding method which includes cleaning, joining, and annealing of the substrate 110 on which the bonding layer 190 is disposed, and the carrier substrate 210. A bonding strength between the substrate 110 on which the bonding layer 190 is disposed and the carrier substrate 210 may be such that the substrate 110 is supported by the carrier substrate 210 in a subsequent back grinding process, and the carrier substrate 210 is easily separated. In some embodiments, the operation of bonding the substrate 110 to the carrier substrate 210 such that the front-side surface 110F of the substrate 110 faces the carrier substrate 210 (S170) may be performed by performing various processes in addition to the SDB process. For example, after an adhesive layer including an adhesive material is further formed on the upper surface of the bonding layer 190, the substrate 110 on which the bonding layer 190 is disposed may be bonded to the carrier substrate 210.

Since the substrate 110 is bonded to the carrier substrate 210 such that the front-side surface 110F of the substrate 110 faces the carrier substrate 210, the back-side surface 110B of the substrate 110 may be exposed to the outside.

Referring to FIGS. 4, 12A, and 12B together, the method of manufacturing a semiconductor device according to an embodiment may include removing the first dielectric film 130, the doped dielectric film 150, and the second dielectric film 170, each remaining on the bevel region and polishing the substrate 110 (S180). The operation of polishing the substrate 110 (S180) may be performed by polishing the back-side surface 110B of the substrate 110. In some embodiments, the operation of removing the first dielectric film 130, the doped dielectric film 150, and the second dielectric film 170, each remaining on the bevel region and polishing the substrate 110 (S180), may include a back lap process or a back grind process of the substrate 110. In some embodiments, the operation of polishing the substrate 110 (S180) may include chemical mechanical polishing, wet etching, or dry etching, or a combination thereof.

After the operation of removing the first dielectric film 130, the doped dielectric film 150, and the second dielectric film 170, each remaining on the bevel region and polishing the substrate 110 (S180), forming the back-side power structures 114 on the back-side surface 110B of the substrate 110 may be performed. The back-side power structures 114 may pass through the substrate 110 in the vertical direction Z, and may be connected to the via power rails 123 inside the first dielectric film 130.

Referring to FIGS. 4, 13A, and 13B together, forming the back-side wiring structures 231 and the back-side insulating film 230 on the back-side surface 110B of the substrate 110 (S190) may be included. The plurality of back-side wiring structures 231 connected to the back-side power structures 114 may be formed on the back-side surface 110B of the substrate 110. A process of forming the plurality of back-side wiring structures 231 is substantially similar to the process of forming the plurality of front-side wiring structures 121 described above and thus repeated description thereof is omitted for conciseness. The operation of forming the back-side wiring structures 231 and the back-side insulating film 230 on the back-side surface 110B of the substrate 110 (S190) may include forming the back-side wiring structures 231 on the back-side surface 110B of the substrate 110, and forming the back-side insulating film 230 on the back-side surface 110B of the substrate 110.

The operation of forming the back-side wiring structures 231 on the back-side surface 110B of the substrate 110 may include the BEOL process. In some embodiments, the BEOL process may include a contact formation operation, a wiring pattern formation operation, a dielectric film formation operation, a via hole formation operation, a via plug formation operation, and a passivation formation operation.

Thereafter, although not shown, a connection member connected to the back-side wiring structure 231 may be formed on the back-side insulating film 230, and the connection member may include conductive bumps and bump pads. The connection member may include conductive material, and the conductive bumps are formed through various methods such as a vacuum deposition method, an electroplating method, a solder jetting method, a wire bonding method, a stencil screen printing method, and the like. The bump pads may be formed through a pulse plating method or a direct current plating method.

After forming the connection member, a process of separating the carrier substrate 210 therefrom may be performed. After the carrier substrate 210 is separated, a process of dicing the substrate 110 may be performed along a scribe lane to individuate each semiconductor device therefrom.

While various embodiments have been particularly shown and described with reference to the drawings, it will be understood that various changes in form and details may be made therein without departing from the spirit and scope of the following claims.

What is claimed is:

1. A method of manufacturing a semiconductor device, the method comprising:
forming a first dielectric film on a front-side surface of a substrate that has the front-side surface and a back-side surface;
doping a surface of the first dielectric film with impurities to form a doped dielectric film covering at least a portion of the first dielectric film;
forming a second dielectric film on the doped dielectric film; and
polishing the second dielectric film by a chemical mechanical polishing (CMP) method,
wherein the doped dielectric film has a polishing rate less than a polishing rate of each of the first dielectric film and the second dielectric film.

2. The method of claim 1, wherein the doped dielectric film is more hydrophobic than the first dielectric film and the second dielectric film.

3. The method of claim 1, wherein the impurities include carbon (C), boron (B), or silicon (Si), or a combination thereof.

4. The method of claim 1, wherein the doped dielectric film includes a composition of SiOₓC_{y}N_{z}, where x is a number greater than 0 but not more than 3, y is a number greater than 0 but not more than 3,and z is a number greater than 0 but not more than 3.

5. The method of claim 1, wherein the polishing exposes an upper surface of the doped dielectric film, and the upper surface of the doped dielectric film has a flat profile.

6. The method of claim 1, further comprising:
before the polishing, etching a portion of each of the first dielectric film, the second dielectric film, the doped dielectric film, and the substrate to form an edge trench,
wherein the etching exposes a portion of the substrate on a bottom surface of the edge trench, and exposes a portion of each of the first dielectric film, the second dielectric film, and the doped dielectric film on a sidewall of the edge trench.

7. The method of claim 6,
wherein an upper surface of the doped dielectric film adjacent to the edge trench has a flat profile.

8. The method of claim 1, further comprising
before forming the first dielectric film,
forming a front-side wiring structure on the front-side surface of the substrate,
wherein the first dielectric film surrounds the front-side wiring structure.

9. The method of claim 1, wherein the polishing exposes the doped dielectric film, and the method further comprises:
after the polishing, forming a bonding layer on the doped dielectric film that is exposed.

10. The method of claim 1, further comprising:
after the polishing,
bonding the substrate to a carrier substrate so that the front-side surface of the substrate faces the carrier substrate.

11. The method of claim 10, further comprising:
after the bonding of the substrate to the carrier substrate, polishing the back-side surface of the substrate.

12. The method of claim 10, further comprising:
after bonding the substrate to the carrier substrate, forming a back-side wiring structure on the back-side surface of the substrate; and
forming a back-side insulating layer surrounding the back-side wiring structure.

13. The method of claim 1,
wherein the first dielectric film is formed to have a thickness of the first dielectric film in a vertical direction that is within a range of about 400 nanometers to about 600 nanometers.

14. A method of manufacturing a semiconductor device, the method comprising:
providing a substrate having a front-side surface and a back-side surface, the substrate including a plurality of fin-type active regions extending in a vertical direction from the front-side surface;
forming a plurality of source/drain regions respectively contacting the plurality of fin-type active regions;
forming a source/drain contact contacting at least one of the plurality of source/drain regions;
forming a via power rail on the front-side surface of the substrate;
forming a front-side wiring structure electrically connected to the via power rail and the source/drain contact;
forming a first dielectric film on the front-side surface of the substrate, the first dielectric film extending in the vertical direction to surround the front-side wiring structure on the front-side surface of the substrate;
doping a surface of the first dielectric film with impurities to form a doped dielectric film that covers at least a portion of the first dielectric film;
forming a second dielectric film on the doped dielectric film; and
polishing the second dielectric film by a chemical mechanical polishing (CMP) method,
wherein the doped dielectric film has a polishing rate less than a polishing rate of each of the first dielectric film and the second dielectric film.

15. The method of claim 14, further comprising:
after the polishing, forming a back-side power structure that penetrates the substrate and that is electrically connected to the via power rail.

16. The method of claim 15, further comprising:
forming a back-side wiring structure that is connected to the back-side power structure on the back-side surface of the substrate; and
forming a back-side insulating layer that surrounds the back-side wiring structure.

17. A method of manufacturing a semiconductor device, the method comprising:
providing a substrate having a front-side surface and a back-side surface, the substrate including a plurality of fin-type active regions that extend in a vertical direction from the front-side surface;
forming a plurality of source/drain regions respectively contacting the plurality of fin-type active regions;
forming a source/drain contact that contacts at least one of the plurality of source/drain regions;
forming a via power rail on the front-side surface of the substrate;
forming a front-side wiring structure that electrically connects to the via power rail and the source/drain contact;
forming a first dielectric film on the front-side surface of the substrate, the first dielectric film extending in the vertical direction to surround the front-side wiring structure on the front-side surface of the substrate;
forming a doped dielectric film that covers at least a portion of a surface of the first dielectric film, the doped dielectric film including carbon (C), boron (B), or silicon (Si), or a combination thereof;
forming a second dielectric film on the doped dielectric film;
polishing the second dielectric film by a chemical mechanical polishing method;
polishing the back-side surface of the substrate;
forming a back-side power structure that penetrates the substrate and that electrically connects to the via power rail;
forming a back-side wiring structure that connects to the back-side power structure on the back-side surface of the substrate; and
forming a back-side insulating layer that surrounds the back-side wiring structure,
wherein the doped dielectric film has a polishing rate less than a polishing rate of each of the first dielectric film and the second dielectric film.

18. The method of claim 17,
wherein the doped dielectric film includes a composition of SiOₓC_{y}N_{z}, where x is a number greater than 0 but not more than 3, y is a number greater than 0 but not more than 3,and z is a number greater than 0 but not more than 3.

19. The method of claim 17,
wherein forming the doped dielectric film comprises doping the surface of the first dielectric film with C, B, or Si, or a combination thereof, by an ion implantation process.

20. The method of claim 17,
wherein the doped dielectric film is more hydrophobic than the first dielectric film and the second dielectric film.
